(19) United States
(12) Patent Application Publication
(10) Pub. No.: US 2025/0046891 A1
(43) Pub. Date: Feb. 6, 2025

(54) PREDICTION OF BATTERY FAILURE THROUGH THERMAL SIGNATURES

(71) Applicant: National Technology & Engineering Solutions of Sandia, LLC, Albuquerque, NM (US)

(72) Inventors: Wyatt Lea Hodges, Albuquerque, NM (US); Joshua Hieb Lamb, Arlington, VA (US); Sean Lubner, Cambridge, MA (US)

(21) Appl. No.: 18/228,453

(22) Filed: Jul. 31, 2023

(51) Int. Cl. H01M 10/44; G01R 31/367; G08B 17/06

(52) U.S. Cl. CPC H01M 10/443; G01R 31/367; G08B 17/06; G01K 7/16; G01R 31/2837

(57) ABSTRACT

The electrothermal “3 omega” technique is used to monitor thermal signatures on a battery cell during charge cycling. Changes in first and third harmonic voltages are measured during cycling and potential causes are identified. When a shorter-term moving average of the resistance thermography 3ω voltage on one or more of a plurality of frequency bands deviates from a longer-term moving average of the resistance thermography 3ω voltage by more than a predetermined threshold, starting and controlling an alarm process can include replacing the battery cell. This work shows the potential of the 3 omega technique to quickly detect signs of cell failure during operation.

### STATEMENT OF GOVERNMENT INTEREST

This invention was made with United States Government support under Contract No. DE-NA0003525 between National Technology & Engineering Solutions of Sandia, LLC and the United States Department of Energy. The United States Government has certain rights in this invention.

### BACKGROUND

As batteries are increasingly adopted for energy storage solutions in the electrical grid, safety and reliability are of critical concern. A primary safety issue is energy release in the form of thermal runaway and cascading failure of battery cells. Prediction and prevention of catastrophic failure is critical to safe and reliable energy storage technology. To address these problems, a variety of techniques have been implemented, including impedance measurements for diagnostics and modeling to predict failure conditions. However, more in operando measurement techniques are needed to assess whether battery cells in use are approaching failure. Since batteries often fail from overheating and resulting thermal runaway, thermal signatures represent an ideal sensing technique to diagnose battery cell health during operation.

Resistance thermometry enables thermal measurements without requiring optical access, enabling in operando measurements of battery thermal properties. The so called “3ω” technique is a resistance thermometry technique that excites a metal heater line with alternating current at frequency ω, creating a temperature fluctuation in the line at 2ω. Due to temperature coefficient of resistance, α, there is a corresponding change in resistance of the heater line at frequency of 2ω. The 1ω current interacts with the 2ω resistance to create voltage signals at frequencies of 1ω and 3ω. The 3ω voltage is of particular interest, as thermal conductivity of the sample can be obtained without any information about volumetric heat capacity (ρCₚ). As a 4-point probe technique, the measurement is insensitive to electrical contact resistances. As an AC measurement, the 3ω technique is also insensitive to thermal contact resistances.

“Traditional” measurements using the 3ω technique sweep a wide range of excitation frequencies and the resulting 3ω voltages are used to fit for a thermal conductivity (k) of the sample. Fitting for thermal conductivity can be done using the in-phase 3ω voltage using the slope method, or the out-of-phase voltage in the low frequency limit. Additional fitting methods use the analytical solution to fit any thermal properties of interest in the sample. Because of the periodic heat input, measurements at different frequencies will be sensitive to different properties of the layer stack. This is due to the “thermal penetration depth”, a characteristic length scale determining the distance from the heat source the heat will diffuse. It is typically defined as

$${L}_{p} ∝ \sqrt{\frac{2 k}{ω ρ {C}_{p}}} . \qquad ( 1 )$$

Because the thermal penetration depth will vary for different excitation currents, it is expected that certain frequencies will be optimal for sensing specific properties. The 3ω technique has been used in battery systems to take measurements of thermal boundary conductance (TBCs), as well as lithium buildup. The previous work shows that the overall thermal resistance of batteries is expected to change as active components degrade over the course of cycling, through decreased contact quality and decreased thermal conductivity of anodes and cathodes. Increased thermal resistance of batteries will lead to increases in the measured 3ω voltages, but since the measurement occurs at the same location as the heating, complex fitting can be required to determine the thermal property change that causes the change in voltage. With thin layers and variation between samples, it can become difficult to determine what physical effect the degradation corresponds to. In addition, battery measurements have previously been done by either (a) doing measurements of many excitation current frequencies in series or (b) by measuring components outside of cycling environments. While this does provide more complete data, it does not offer the fastest possible response time, which could be critical for identifying cells in danger of failure in the field, and potentially preventing of catastrophic failure.

### SUMMARY

There is a need for the following embodiments of the present disclosure. Of course, the present disclosure is not limited to these embodiments

An electrically insulating layer is fabricated on a battery cell, and a metal heater line is fabricated on top of the insulating layer. The heater line is excited by an alternating current, and as explained above the resulting temperature of the heater line will depend on the thermal properties of the battery cell. The temperature is tracked by changes in the resistance of the heater line, through monitoring of the third harmonic voltage resulting from the AC current excitation.

The thermal properties of the battery cell will change through cycling and will be the cause for loss of charge capacity of the battery. By tracking the changes in the measured thermal signature (temperature) the health of the battery cell can be ascertained and failure can be predicted.

Real-time monitoring of the 3ω voltages during battery cycling at a limited number of frequencies offers the fastest response time to changes in the thermal properties of the cell and the faster detection time than (compared to) full frequency sweeps. In this work a model was constructed to estimate the changes in 3ω voltages that would occur in a battery cell during cycling using an analytical solution. The model was used to select frequencies to monitor during a cycling test of a battery. An experimental setup was designed to monitor the 3ω voltages continuously during cycling. Using this setup, 10 and 3ω voltages were monitored by a sensor attached to a thin-film battery in a pouch cell in the presence of an electrolyte. Changes in 1ω and 3ω voltages were observed as the cell approached failure.

According to an embodiment of the present disclosure, a process comprises: monitoring resistance thermography 3ω voltage from a temperature sensor coupled to a battery cell on each of a plurality of frequency bands that are different from one another, wherein monitoring resistance thermography 3ω voltage comprises subtracting 1ω voltage; scanning the plurality of frequency bands while monitoring comprising: hopping to a first of the plurality of frequency bands before monitoring; hopping to a second of the plurality of frequency bands after monitoring; and omitting sweeping frequencies between the first of the plurality of frequency bands and the second of the plurality of frequency bands; repeatedly charge-discharge cycling the battery cell while monitoring; in response to a shorter-term moving average of the resistance thermography 3ω voltage on one or more of the plurality of frequency bands deviating from a longer-term moving average of the resistance thermography 3ω voltage by more than a predetermined threshold, starting an alarm process; and controlling the alarm process comprising replacing the battery cell, wherein a first of the plurality of frequency bands comprises an out-of-phase 3ω voltage local maximum, wherein a second of the plurality of frequency bands comprises an in-phase 3ω voltage local maximum, wherein a third of the plurality of frequency bands comprises a low end of 3ω voltage frequencies that can be measured without excessive noise, and wherein a fourth of the plurality of frequency bands comprises a 3ω voltage frequency that remains substantially unchanged.

According to another embodiment of the present disclosure, an apparatus for monitoring battery health using thermal signature, comprises: a battery cell; a temperature sensor coupled to the battery cell; and a controller coupled to the temperature sensor and the battery call. The controller is configured to: monitor resistance thermography 3ω voltage from the temperature sensor on each of a plurality of frequency bands that are different from one another; in response to a shorter-term moving average of the resistance thermography 3ω voltage on one or more of the plurality of frequency bands deviating from a longer-term moving average of the resistance thermography 3ω voltage by more than a predetermined threshold, starting an alarm process; and control the alarm process.

These, and other, embodiments of the present disclosure will be better appreciated and understood when considered in conjunction with the following description and the accompanying drawings. It should be understood, however, that the following description, while indicating various embodiments of the present disclosure and numerous specific details thereof, is given for the purpose of illustration and does not imply limitation. Many substitutions, modifications, additions and/or rearrangements may be made within the scope of embodiments of the present disclosure, and embodiments of the present disclosure include all such substitutions, modifications, additions and/or rearrangements.

### BRIEF DESCRIPTION OF THE DRAWINGS

The drawings accompanying and forming part of this specification are included to depict certain embodiments of the present disclosure. A clearer concept of the embodiments described in this application will be readily apparent by referring to the exemplary, and therefore nonlimiting, embodiments illustrated in the drawings (wherein identical reference numerals (if they occur in more than one view) designate the same elements).

FIGS. 1A-1B illustrate a battery cell and a sensor. FIG. 1A is a schematic picture of the layer stack for testing, FIG. 1B shows a sensor on a battery stack.

FIGS. 2A-2B illustrate modeling results. FIG. 2A shows simulated 3ω voltages before and after battery cycling, FIG. 2B shows the difference in the simulated data for cells before and after cycling.

FIGS. 3A-3D illustrate data from battery cycling test. FIG. 3A shows the in-phase 3ω voltage during the test. FIG. 3B shows the measured out-of-phase voltage. FIG. 3C shows the battery cell measured capacity during the test. FIG. 3D shows the time taken for each charge/discharge cycle.

FIGS. 4A-4C illustrate data from battery cycling test. FIG. 4A shows the in-phase 3ω voltage for all frequencies during the test. FIG. 4B shows the measured out-of-phase voltage for all frequencies. FIG. 4C shows the measured 1ω voltages.

FIG. 5 illustrates a flow diagram of a process that can be implemented by a computer program.

FIG. 6 illustrates a block diagram of a system.

FIG. 7 illustrates a flow diagram of a process that can be implemented by a computer program.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well-known materials, techniques, components and equipment are omitted so as not to unnecessarily obscure the embodiments of the present disclosure in detail. It should be understood, however, that the detailed description and the specific examples are given by way of illustration only and not by way of limitation. Various substitutions, modifications, additions and/or rearrangements within the scope of the underlying inventive concept will become apparent to those skilled in the art from this disclosure.

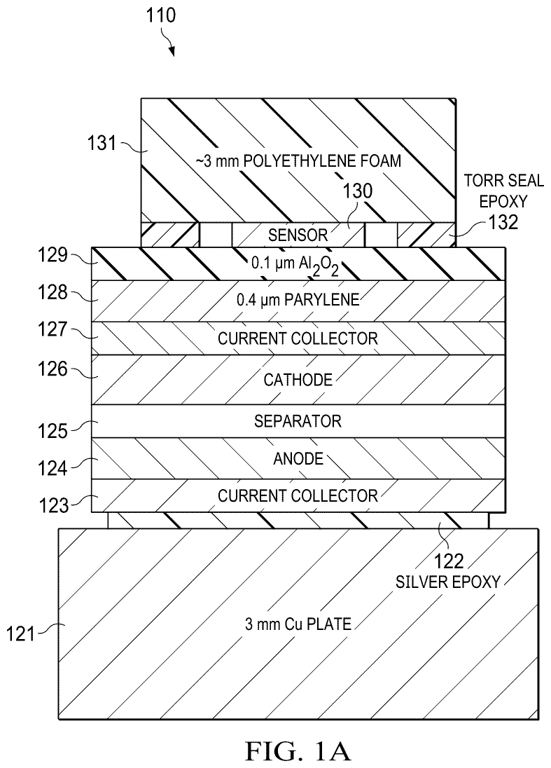

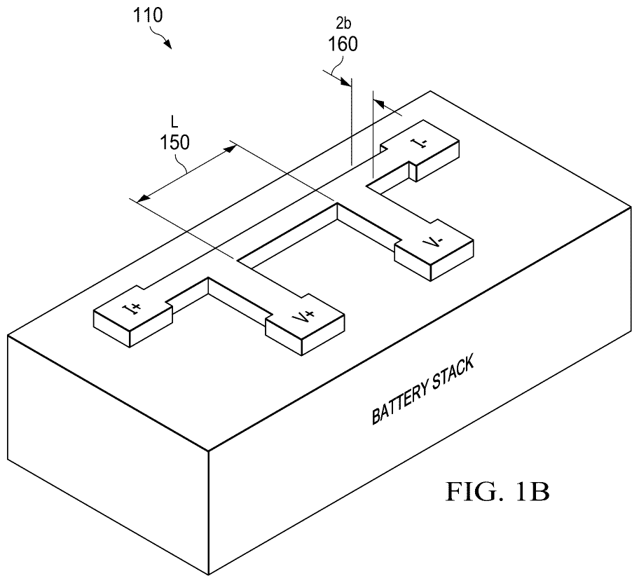

Referring to FIG. 1A, a battery stack 110 includes a copper plate 121 coupled using a silver epoxy 122 to a first current collector 123. The current collector is connected to an anode 124. The anode 124 is spaced apart from a cathode 126 by a separator 125. The cathode 126 is connected to a second current collector 127. The second current collector 127 is connected to a Parylene layer 128. The Parylene layer 128 is coupled to an alumina layer 129. A sensor 130 is located between the alumina layer 129 and polyethylene foam 131 that is sealed to the alumina layer 129 using epoxy 132.

The properties used for the battery stack are summarized in Table 1.

TABLE 1
Thermal property values used in battery stack

| Material | k [W/m K] | C [MJ/m³ K] | d [μm] |
|---|---|---|---|
| Polyethylene foam | 0.024 | 0.016 | 3000 |
| Alumina | 17 | 3.08 | 0.1 |
| Parylene | 0.15 | 0.96 | 400 |
| Al current collector | 237 | 2.42 | 23 |
| Cathode | 0.828 | 3.51 | 74 |
| Separator | 0.3 | 2.18 | 26 |
| Anode | 1.44 | 2.03 | 96 |
| Copper current collector | 401 | 3.44 | 12 |
| Silver Epoxy | 10 | 2 | 50 |
| Copper | 401 | 3.44 | 3000 |
| Pouch | 0.15 | 3 | 159 |

In this model additional layers were added to represent TBCs (thermal boundary conductance). These layers were modeled as being 10 nm thick, with thermal resistance of 1 cm² K/W before cycling, and 4 cm² K/W after cycling. This value was chosen for initial estimations to be close to literature values.

Referring to FIG. 1B, sensor dimensions were heater length 150 (L) of 3 mm and heater width 160 (2b) (i.e., heater half width b=32.5 μm), matching the fabricated heater lines. Heater line resistance was 4.2Ω with α of 0.02, matching measured values for the sensor.

An experimental setup was constructed. A Zurich HF2LI provided a voltage signal, which was put through a V-to-I conversion circuit on a breadboard, and that current was flowed through a 3ω sensor and a potentiometer with a matched resistance. The Zurich HF2LI took voltage readings at a frequency of 3ω, where ω is the frequency of the current input. The signal measured was a subtraction of the voltage drop over the sensor and the potentiometer using the lock-in amplifier's differential mode. The voltage subtraction is done to increase sensitivity to the 3ω voltage, which is typically 1000 times smaller than the 1ω voltage. The voltage subtraction allows for smaller voltage range settings to be used, and therefore more bits associated with the magnitude of the 3ω signal.

The measurement system was verified to be working correctly by traditional 3ω frequency sweep measurements verifying the thermal conductivity of SiO₂ microscope slide samples. The 3ω heater line was deposited by evaporation of 300 nm of gold on a shadow mask, with a 5 nm Titanium adhesion layer between the gold and glass. Glass microscope slide thermal conductivity was found to be 1.28±0.13 W/m K, matching literature value of 1.29 W/m K.

For battery cycling tests, the 300 sensor was fabricated onto the samples of interest with an underlying dielectric layer, to prevent undesired electrical conduction pathways. To do this, a measurement stack based on work by Lubner, et al. was fabricated. The combined sensor and battery geometry is shown in FIG. 1a. This design uses 400 nm parylene to provide mechanical and electrical isolation for the 3ω sensor, and an overlayer of 100 nm alumina to provide more complete coverage by filling any pinholes. The deposition of the parylene was done with a conformal chemical vapor deposition, and the alumina was deposited by atomic layer deposition. The 3ω heater line was deposited by evaporation of 300 nm of gold on a shadow mask, with a 5 nm Titanium adhesion layer evaporated directly onto the alumina before the shadow masked gold. Both the gold and titanium were deposited at 1 nm/s to ensure fully dense films. A top view schematic of a 3ω sensor is shown in FIG. 1b.

The electrical leads of the 3ω wires were connected to the breadboard using 36 gage copper wire with a plastic insulated shielding. The connection was made with AI Technology EG8050 silver epoxy cured at 150° C.

During the cycling test, four frequencies were excited with 17 mA of current, and 3ω voltage was monitored simultaneously. Four is the maximum number of simultaneous excitations at ω and monitoring at 3ω that the Zurich HF2LI can provide. The frequencies in the first tests were multiplicatively separated by a factor of 4.71 in an attempt to eliminate interference between excitation frequencies while maintaining the maximum range of penetration depths. The lock-in time constants were set at

$$\frac{24 π}{ω} ,$$

with 8th order filters on each channel.

The experimental cell was tested in a temperature-controlled chamber (Tenney TUJR) set to 22° C. The current and voltage were controlled by a Maccor 4400 battery cell test controller. Current is reported here in the form of C/x, where C is the nominal capacity in Amp-hours (0.03 Amp-hours for this cell) and x if the number of hours needed to fully charge the current, giving a rate as a DC current. Formation was completed at steps of C/100 (0.3 mA), C/10 (3 mA) and C/3 (10 mA) charge rates to 4.2V and discharge rates of C/10 to 3.0V. Following formation, the cell was cycled with the same voltage parameters at 1 C rate for 500 cycles. The first 100 cycles, completed in 76 hours, were determined to be end of test due to high capacity fade at this rate. The cell was subsequently tested at lower rates, C/10 charge and discharge currents, for 500 cycles with the voltage parameters of 3.0V to 4.2V. This testing resulted in cell failure at approximately 405 cycles.

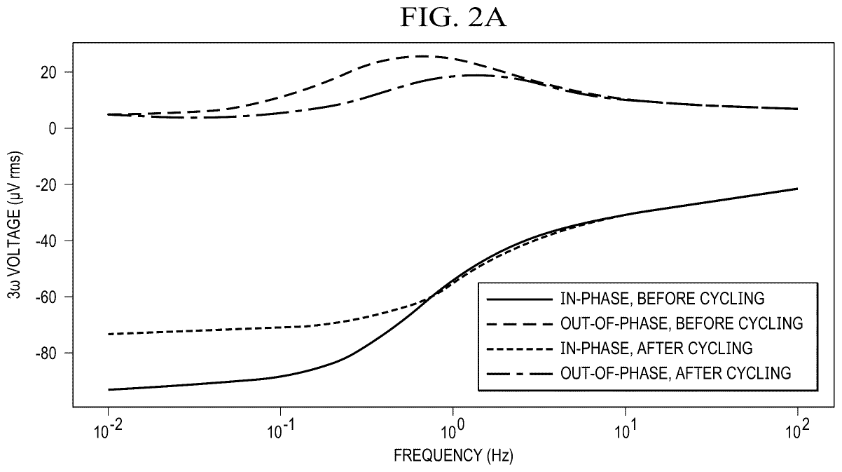

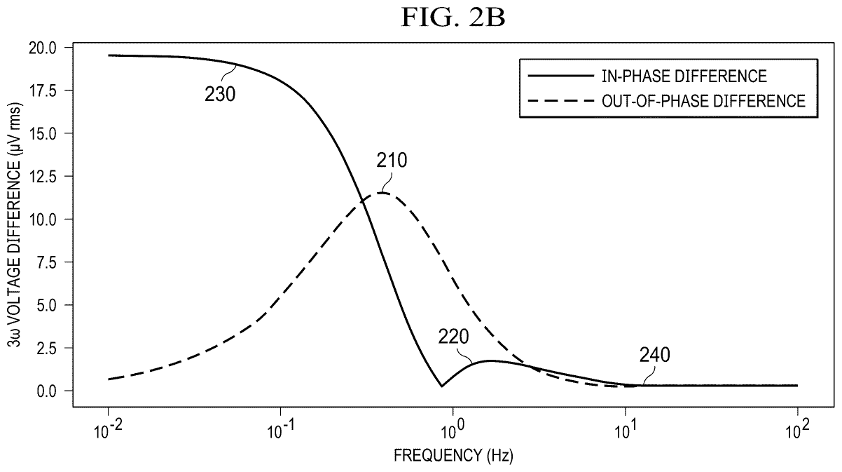

Using the model and parameters outlined in Table 1, models of 3ω voltages before and after cycling were calculated. The results of these calculations are shown in FIG. 2A. FIG. 2B shows the difference between the voltages before and after cycling.

Referring to FIG. 2B, the high frequencies do not show significant change, since they are primarily sensitive to the thermal properties of the dielectric layers, aluminum current collector, and the cathode, which remain constant through cycling. At frequencies below 10 Hz, the measurement has sensitivity to the TBCs (thermal boundary conductance) that vary in this model. As Lₚ increases, the in-phase 3 omega voltage decreases at all modeled frequencies, causing the voltage difference in FIGS. 2A-2B. The out-of-phase voltage has a local maximum at approximately 0.5 Hz before cycling and a local maximum at approximately 1 Hz after cycling. Based on the results of this modeling, the frequencies 0.051, 0.260, 1.150, and 10.3 Hz were selected for testing. A local out-of-phase maximum 210 at approximately 0.260 Hz is selected as a local maximum of the out-of-phase voltage plot. A local in-phase maximum 220 at approximately 1.150 is selected as a local maximum of the in-phase voltage plot. A low reference 230 at approximately 0.0510 was selected because that is at the low end of frequencies that can be measured without excessive noise, and is still close to the maximum of the in-phase difference plot. A high reference 240 at approximately 10.3 Hz was selected for future testing because it is expected to remain unchanged, and would serve as a validation that the model is accurately predicting the behavior of the test system. All four frequencies are multiplicatively spaced by greater than a factor of 4.71, which is preferred to prevent undesired interference signals.

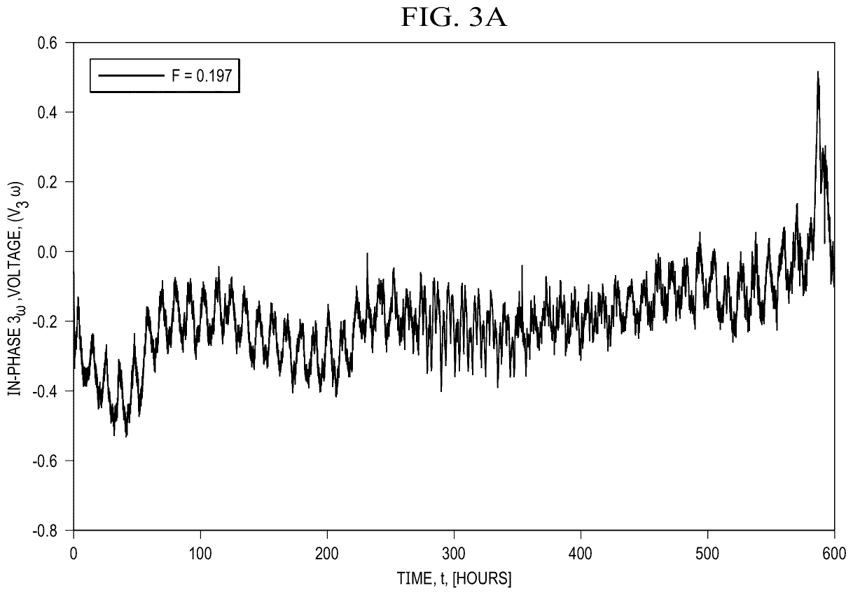

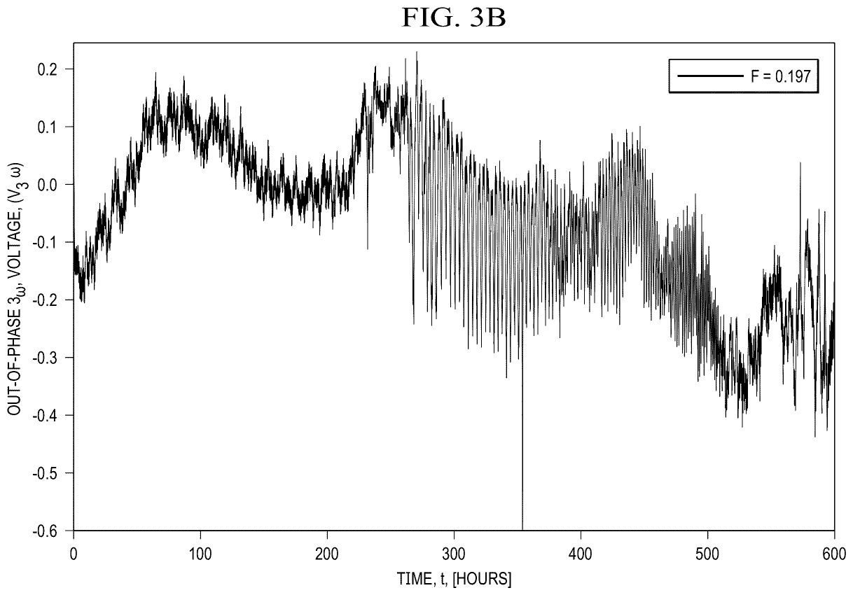

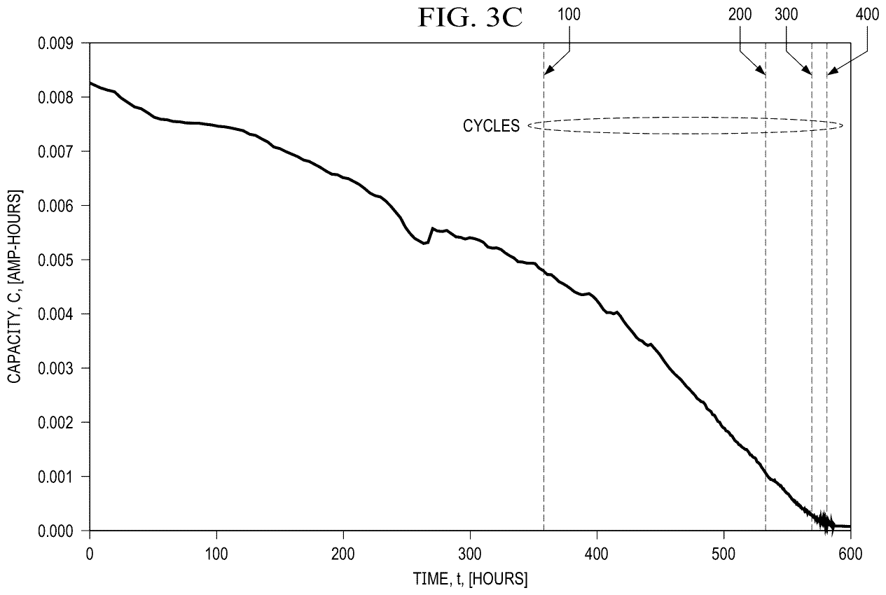

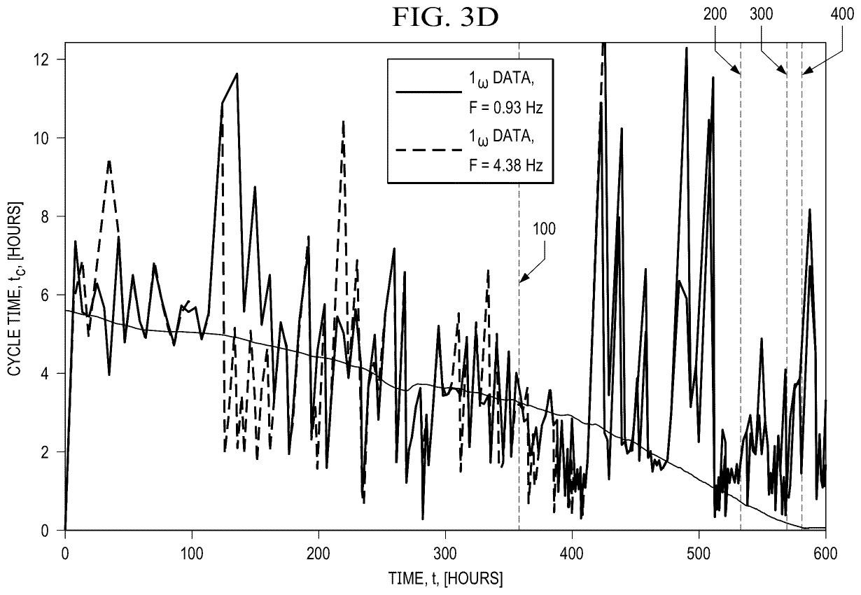

In another embodiment, the frequencies continuously real-time monitored were 0.0419, 0.197, 0.930, and 4.38 Hz. These numbers differ from the results suggested by the modeling in the previous section due to improvements made to the model after the cycling test had begun. The results from continuous real-time monitoring of 3ω voltages at a frequency of 0.197 are shown in FIGS. 3A and 3B, after applying one moving average filter of 2650 seconds. This was done to filter noise out at the dominant frequency, as measured by a fast Fourier analysis. Even after the moving average filter is applied, the other measured frequencies contained much more noise.

FIG. 3C shows the measured cell capacity as a function of test time. Towards the end of the test, the in-phase 3ω voltage trends generally towards 0, with a corresponding continuous decrease in capacity. FIG. 3D shows cycle time as a function of accumulated hours.

Embodiments can include intermittent monitoring. This intermittent monitoring can (like continuous monitoring) provide real-time actionable information on the heath of the battery cell or other device. For example, a pause of 30 minutes can alternative with monitoring for 30-60 seconds.

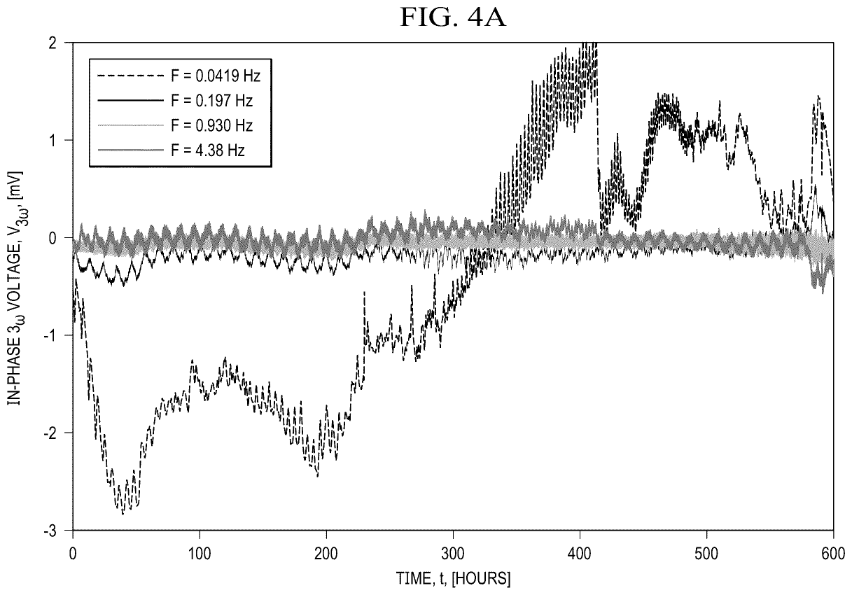

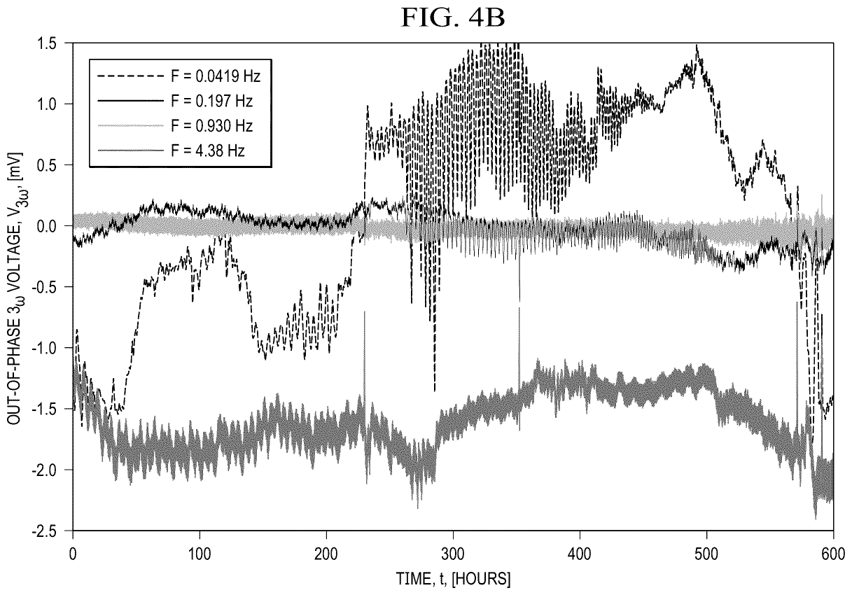

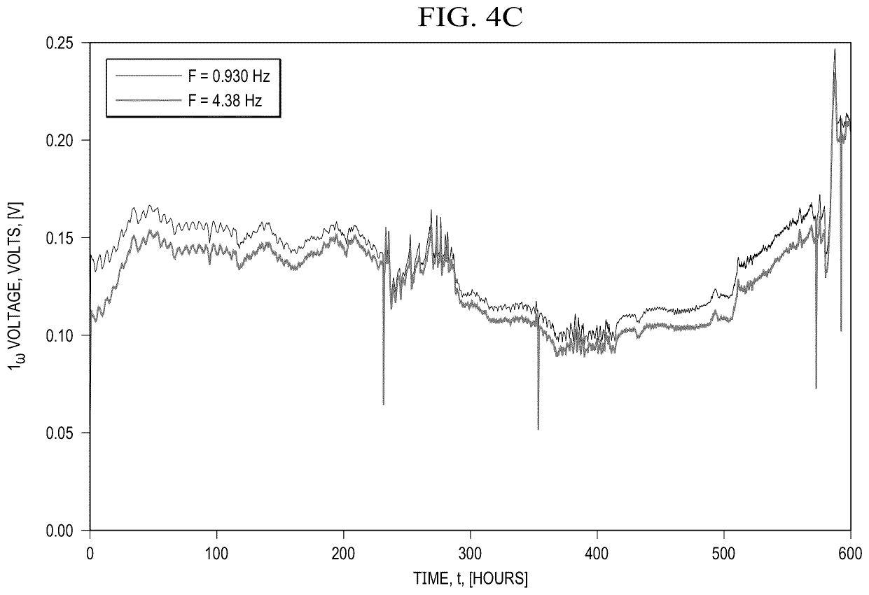

Referring to FIGS. 4A-4C, data from a battery cycling test is shown. FIG. 4A shows the measured in-phase 3ω voltage for all frequencies during the test. The frequencies were 0.0419, 0.197, 0.930, and 4.38 Hz. FIG. 4B shows the measured out-of-phase voltage for all frequencies during the test. FIG. 4C shows the measured 100 voltages for all frequencies during the test.

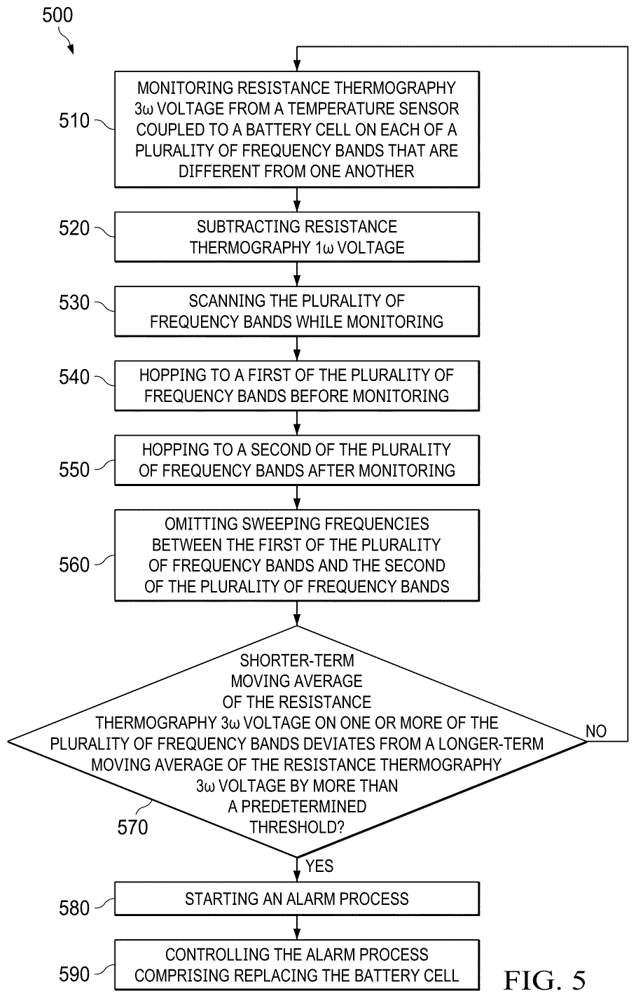

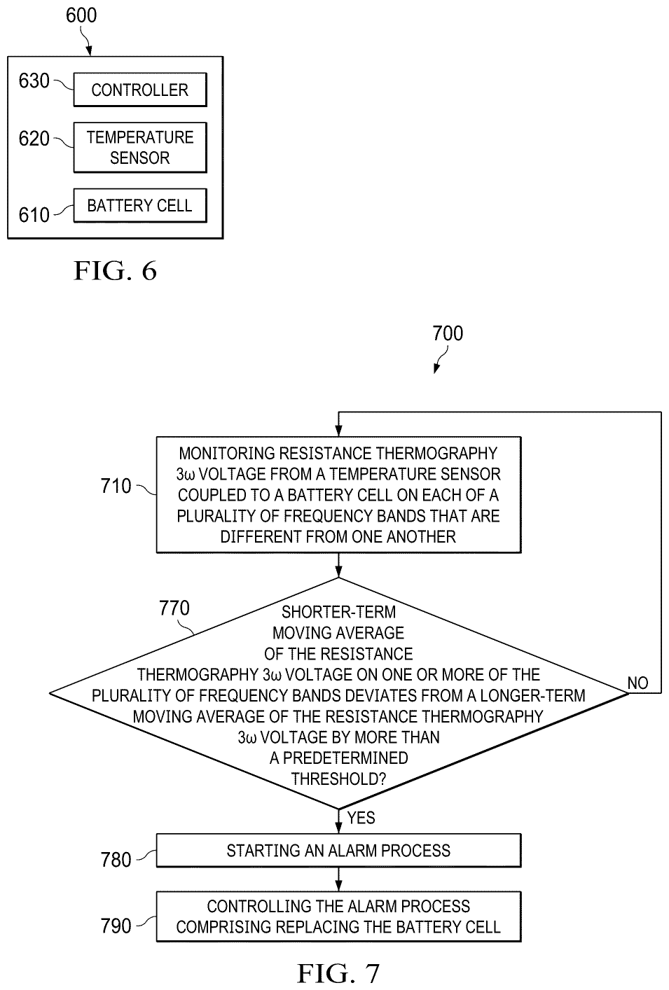

With reference next to FIG. 5, a flowchart of a process 500 is depicted in accordance with an illustrative embodiment. The process in FIG. 5 can be implemented in hardware, software, or both. When implemented in software, the process can take the form of program instructions that are run by one of more processor units located in one or more hardware devices in one or more computer systems. For example, the process can be implemented in controller 630 in computer system 600 in FIG. 6.

The process 500 begins by monitoring resistance thermography 3ω voltage from a temperature sensor coupled to a battery cell on each of a plurality of frequency bands that are different from one another (step 510). This is followed by subtracting 1ω voltage (step 520). This is followed by scanning the plurality of frequency bands while monitoring (step 530). This is followed by hopping to a first of the plurality of frequency bands before monitoring (step 540). This is followed by hopping to a second of the plurality of frequency bands after monitoring (step 550). This is followed by omitting sweeping frequencies between the first of the plurality of frequency bands and the second of the plurality of frequency bands (step 560). In response to a shorter-term moving average of the resistance thermography 3ω voltage on one or more of the plurality of frequency bands deviating from a longer-term moving average of the resistance thermography 3ω voltage by more than a predetermined threshold (step 570), the process starts and controls an alarm process (step 580). In the alternative, the process reverts back to step 510. Controlling the alarm process can include replacing the battery cell (step 590). The process terminates thereafter.

With reference next to FIG. 6, a block diagram of computer system 600 is illustrated. A battery cell 610 is coupled to a temperature sensor 620. A controller 630 is coupled to both the temperature sensor 620 and the battery cell 610. The controller 630 is configured for monitoring resistance thermography 3ω voltage from a temperature sensor coupled to a battery cell on each of a plurality of frequency bands that are different from one another, wherein monitoring resistance thermography 3ω voltage comprises subtracting 1ω voltage. The controller 630 is also configured for scanning the plurality of frequency bands while monitoring comprising: hopping to a first of the plurality of frequency bands before monitoring; hopping to a second of the plurality of frequency bands after monitoring; and omitting sweeping frequencies between the first of the plurality of frequency bands and the second of the plurality of frequency bands. The controller 630 is also configured for repeatedly charge-discharge cycling the battery cell while monitoring; in response to a shorter-term moving average of the resistance thermography 3ω voltage on one or more of the plurality of frequency bands deviating from a longer-term moving average of the resistance thermography 3ω voltage by more than 35-90 percent, starting an alarm process; and controlling the alarm process comprising replacing the battery cell. A first of the plurality of frequency bands can include an out-of-phase 3ω voltage local maximum. A second of the plurality of frequency bands can include an in-phase 3ω voltage local maximum. A third of the plurality of frequency bands can include a low end of 3ω voltage frequencies that can be measured without excessive noise. A fourth of the plurality of frequency bands can include a 3ω voltage frequency that remains substantially unchanged.

With reference next to FIG. 7, a flowchart of a process 700 for monitoring battery health using thermal signature is depicted in accordance with an illustrative embodiment. The process in FIG. 7 can be implemented in hardware, software, or both. When implemented in software, the process can take the form of program instructions that are run by one of more processor units located in one or more hardware devices in one or more computer systems. For example, the process can be implemented in controller 630 in computer system 600 in FIG. 6.

The process 700 begins by monitoring resistance thermography 3ω voltage from a temperature sensor coupled to a battery cell on each of a plurality of frequency bands that are different from one another (step 710). In response to a shorter-term moving average of the resistance thermography 3ω voltage on one or more of the plurality of frequency bands deviating from a longer-term moving average of the resistance thermography 3ω voltage by more than a predetermined threshold (step 770), the process starts and controls an alarm process (step 780). In the alternative, the process goes back to step 710. Controlling the alarm process can include replacing the battery cell (step 790). The process terminates thereafter.

Embodiments include a new measurement system that in addition to the traditional 3ω measurements can also monitor 3ω voltages continuously in dynamically changing systems. Embodiments include real-time 3ω measurements-monitoring a battery cell through cycling.

The 30 measurement system can provide measurements to battery modelers that were not accessible previously. Potential measurements include effective thermal conductivities of battery cell stacks and measurements of individual battery component thermal properties. Thermal property measurements can provide inputs to the models, verifying quantities (such as thermal conductivities of anode and cathode materials) that are not typically measured. Similar measurements can also be made on the effective thermal properties of the battery material stack, which would provide validation of simulations on these stacks. Embodiments show the ability to integrate sensors into battery stacks that will be cycled, measurements of thermal properties that can be done before and after cycling without utilizing the real-time monitoring of voltages, and without the need for technique development.

An ability to monitor the health of battery cells during use would greatly increase battery reliability and safety. The 3ω technique is ideally positioned to provide these measurements, because unlike many other thermal property measurement techniques it does not require optical access. The ability of the 1ω voltage to verify cycling time provides an alternate avenue to verify cycling times, and has potential to be developed further in parallel to the real-time 3ω measurements.

Using electrothermal techniques to monitor battery signatures has the potential to sense a variety of different cycling effects. The preliminary testing in this project showed two measurable quantities to get information about cell degradation: first and third harmonic voltages in a periodically excited heater line. Both voltage signatures can be obtained in real-time simultaneously, and different harmonics can be used to get different information from one excitation frequency. Embodiments can use different excitation waveforms, such as DC or square waves, to obtain customized information based on the desired application. Different waveforms may increase sensitivity to parameters of interest. Multiple sensors could also be implemented to get spatial information about the sample in real time, both by applying multiple sensors to the same layer in the stack and fabricating sensors in between many batteries in a multi-cell stack. Multi-sensor approaches could give more information about where a cell tends to fail to inform cell design. All of these potential approaches for obtaining more information about battery cells during operation require incorporating only a metal heat line with 4 electrical connections, with no optical access during testing necessary.

Data processing has a key role to play in any future efforts. Lock-in time constants provide an averaging window for the signal but may not be the path that will lead to the fastest response time. Other embodiments using an unprocessed signal and entirely digital filters may be able to achieve faster response times, and identify changes in a cell sooner than a lock-in amplifier. This work also used moving averages to process data after the test, and this approach has potential for improvement using more advanced signal processing techniques.

The techniques suggested here have the potential to impact not just battery performance monitoring, but other applications in which thermal signatures measurable by a heater line correlate to other physical effects at the length scales of microns to millimeters.

This project showed the potential of resistance heating to detect thermal signatures which may predict battery failure. Resistance heater lines were used to monitor thermal signatures of a thin film battery cell at multiple harmonics simultaneously. Modeling using an analytical solution showed the ability of the measurement technique to sense changes in thermal boundary resistances which are shown to correlate to the cell approaching failure. Initial testing showed changes in the continuously monitored voltages as the battery cell decreased charge capacity and approached failure.

Embodiments of the present disclosure can be cost effective and advantageous for at least the following reasons. Embodiments of the present disclosure provide a cost-effective, real-time continuous resistance thermography monitoring capability for the health of battery banks since hopping between sensitive frequency bands is much more efficient than sweeping through all of the frequencies. Embodiments of the present disclosure improve quality and/or reduce costs compared to previous approaches.

A computer readable medium is intended to mean non-transitory computer or machine readable program elements translatable for implementing a method of this disclosure. The terms program and software and/or the phrases program elements, computer program and computer software are intended to mean a sequence of instructions designed for execution on a computer system (e.g., a program and/or computer program, may include a subroutine, a function, a procedure, an object method, an object implementation, an executable application, an applet, a servlet, a source code, an object code, a shared library/dynamic load library and/or other sequence of instructions designed for execution on a computer or computer system). The phrase ultrasonic frequency is intended to mean frequencies greater than or equal to approximately 20 KHz. The phrase radio frequency (RF) is intended to mean frequencies less than or equal to approximately 300 GHz as well as the infrared spectrum. The term light is intended to mean frequencies greater than or equal to approximately 300 GHz as well as the microwave spectrum. Group numbers corresponding to columns within the periodic table of the elements use the “New Notation” convention as seen in the CRC Handbook of Chemistry and Physics, 93^{st} Edition (2012).

The term uniformly is intended to mean unvarying or deviating very little from a given and/or expected value (e.g, within 10% of). The term substantially is intended to mean largely but not necessarily wholly that which is specified. The term approximately is intended to mean at least close to a given value (e.g., within 10% of). The term generally is intended to mean at least approaching a given state. The term coupled is intended to mean connected, although not necessarily directly, and not necessarily mechanically. The term proximate, as used herein, is intended to mean close, near adjacent and/or coincident; and includes spatial situations where specified functions and/or results (if any) can be carried out and/or achieved. The term distal, as used herein, is intended to mean far, away, spaced apart from and/or non-coincident, and includes spatial situation where specified functions and/or results (if any) can be carried out and/or achieved. The term deploying is intended to mean designing, building, shipping, installing and/or operating.

The terms first or one, and the phrases at least a first or at least one, are intended to mean the singular or the plural unless it is clear from the intrinsic text of this document that it is meant otherwise. The terms second or another, and the phrases at least a second or at least another, are intended to mean the singular or the plural unless it is clear from the intrinsic text of this document that it is meant otherwise. Unless expressly stated to the contrary in the intrinsic text of this document, the term or is intended to mean an inclusive or and not an exclusive or. Specifically, a condition A or B is satisfied by any one of the following: A is true (or present) and B is false (or not present), A is false (or not present) and B is true (or present), and both A and B are true (or present). The terms a and/or an are employed for grammatical style and merely for convenience.

The term plurality is intended to mean two or more than two. The term any is intended to mean all applicable members of a set or at least a subset of all applicable members of the set. The phrase any integer derivable therein is intended to mean an integer between the corresponding numbers recited in the specification. The phrase any range derivable therein is intended to mean any range within such corresponding numbers. The term means, when followed by the term “for” is intended to mean hardware, firmware and/or software for achieving a result. The term step, when followed by the term “for” is intended to mean a (sub) method, (sub) process and/or (sub) routine for achieving the recited result. Unless otherwise defined, all technical and scientific terms used herein have the same meaning as commonly understood by one of ordinary skill in the art to which this present disclosure belongs. In case of conflict, the present specification, including definitions, will control.

The described embodiments and examples are illustrative only and not intended to be limiting. Although embodiments of the present disclosure can be implemented separately, embodiments of the present disclosure may be integrated into the system(s) with which they are associated. All the embodiments of the present disclosure disclosed herein can be made and used without undue experimentation in light of the disclosure. Embodiments of the present disclosure are not limited by theoretical statements (if any) recited herein. The individual steps of embodiments of the present disclosure need not be performed in the disclosed manner, or combined in the disclosed sequences, but may be performed in any and all manner and/or combined in any and all sequences. The individual components of embodiments of the present disclosure need not be formed in the disclosed shapes, or combined in the disclosed configurations, but could be provided in any and all shapes, and/or combined in any and all configurations. The individual components need not be fabricated from the disclosed materials but could be fabricated from any and all suitable materials.

Various substitutions, modifications, additions and/or rearrangements of the features of embodiments of the present disclosure may be made without deviating from the scope of the underlying inventive concept. All the disclosed elements and features of each disclosed embodiment can be combined with, or substituted for, the disclosed elements and features of every other disclosed embodiment except where such elements or features are mutually exclusive. The scope of the underlying inventive concept as defined by the appended claims and their equivalents cover all such substitutions, modifications, additions and/or rearrangements.

The appended claims are not to be interpreted as including means-plus-function limitations, unless such a limitation is explicitly recited in a given claim using the phrase(s) “means for” or “mechanism for” or “step for”. Sub-generic embodiments of this disclosure are delineated by the appended independent claims and their equivalents. Specific embodiments of this disclosure are differentiated by the appended dependent claims and their equivalents.

What is claimed is:

1. A method of monitoring battery health using thermal signature, comprising:
monitoring resistance thermography 3ω voltage from a temperature sensor coupled to a battery cell on each of a plurality of frequency bands that are different from one another;
in response to a shorter-term moving average of the resistance thermography 3ω voltage on one or more of the plurality of frequency bands deviating from a longer-term moving average of the resistance thermography 3ω voltage by more than a predetermined threshold, starting an alarm process; and
controlling the alarm process.

2. The method of claim 1, further comprising at least one of charging the battery cell while monitoring or discharging the battery cell while monitoring.

3. The method of claim 1, further comprising scanning the plurality of frequency bands while monitoring.

4. The method of claim 3, further comprising hopping to a first of the plurality of frequency bands before monitoring.

5. The method of claim 4, further comprising hopping to a second of the plurality of frequency bands after monitoring.

6. The method of claim 5, further comprising omitting sweeping frequencies between the first of the plurality of frequency bands and the second of the plurality of frequency bands.

7. The method of claim 1, wherein monitoring resistance thermography 3ω voltage comprises subtracting 1ω voltage before monitoring resistance thermography 3ω voltage.

8. The method of claim 1, wherein controlling the alarm process comprises replacing the battery cell that is coupled to the temperature sensor and resetting the alarm.

9. The method of claim 1, wherein monitoring comprises continuous real-time monitoring.

10. The method of claim 1, wherein monitoring comprises intermittent monitoring.

11. The method of claim 1, further comprising repeatedly charge-discharge cycling the battery cell while monitoring.

12. The method of claim 1, wherein a first of the plurality of frequency bands comprises an out-of-phase 3ω voltage local maximum.

13. The method of claim 12, wherein the first of the plurality of frequency bands comprises approximately 0.260 Hz.

14. The method of claim 1, wherein a second of the plurality of frequency bands comprises an in-phase 3ω voltage local maximum.

15. The method of claim 14, wherein the second of the plurality of frequency bands comprises approximately 1.15 Hz.

16. The method of claim 1, wherein a third of the plurality of frequency bands comprises a low end of 3ω voltage frequencies that can be measured without excessive noise.

17. The method of claim 16, wherein the third of the plurality of frequency bands comprises approximately 0.051 Hz.

18. The method of claim 1, wherein a fourth of the plurality of frequency bands comprises a 3ω voltage frequency that remains substantially unchanged.

19. The method of claim 18, wherein the fourth of the plurality of frequency bands comprises approximately 10.3 Hz.

20. A method, comprising:
monitoring resistance thermography 3ω voltage from a temperature sensor coupled to a battery cell on each of a plurality of frequency bands that are different from one another, wherein monitoring resistance thermography 3ω voltage comprises subtracting 1ω voltage;
scanning the plurality of frequency bands while monitoring comprising:
hopping to a first of the plurality of frequency bands before monitoring;
hopping to a second of the plurality of frequency bands after monitoring; and
omitting sweeping frequencies between the first of the plurality of frequency bands and the second of the plurality of frequency bands;
in response to a shorter-term moving average of the resistance thermography 3ω voltage on one or more of the plurality of frequency bands deviating from a longer-term moving average of the resistance thermography 3ω voltage by more than a predetermined threshold, starting an alarm process; and
controlling the alarm process comprising replacing the battery cell.

21. The method of claim 20, further comprising repeatedly charge-discharge cycling the battery cell while monitoring.

22. The method of claim 20, wherein a first of the plurality of frequency bands comprises an out-of-phase 3ω voltage local maximum.

23. The method of claim 20, wherein a second of the plurality of frequency bands comprises an in-phase 3ω voltage local maximum.

24. The method of claim 20, wherein a third of the plurality of frequency bands comprises a low end of 3ω voltage frequencies that can be measured without excessive noise.

25. The method of claim 20, wherein a fourth of the plurality of frequency bands comprises a 3ω voltage frequency that remains substantially unchanged.

26. A method of monitoring battery health using thermal signature, comprising:
monitoring resistance thermography 3ω voltage from a temperature sensor coupled to a battery cell on each of a plurality of frequency bands that are different from one another, wherein monitoring resistance thermography 3ω voltage comprises subtracting 1ω voltage;
scanning the plurality of frequency bands while monitoring comprising:
hopping to a first of the plurality of frequency bands before monitoring;
hopping to a second of the plurality of frequency bands after monitoring; and
omitting sweeping frequencies between the first of the plurality of frequency bands and the second of the plurality of frequency bands;
repeatedly charge-discharge cycling the battery cell while monitoring;
in response to a shorter-term moving average of the resistance thermography 3ω voltage on one or more of the plurality of frequency bands deviating from a longer-term moving average of the resistance thermography 3ω voltage by more than 35-90 percent, starting an alarm process; and
controlling the alarm process comprising replacing the battery cell,
wherein a first of the plurality of frequency bands comprises an out-of-phase 3ω voltage local maximum,
wherein a second of the plurality of frequency bands comprises an in-phase 3ω voltage local maximum,
wherein a third of the plurality of frequency bands comprises a low end of 3ω voltage frequencies that can be measured without excessive noise, and
wherein a fourth of the plurality of frequency bands comprises a 3ω voltage frequency that remains substantially unchanged.

27. An apparatus for monitoring battery health using thermal signature, comprising
a battery cell;
a temperature sensor coupled to the battery cell; and
a controller coupled to the temperature sensor and the battery call,
wherein the controller is configured to:
monitor resistance thermography 3ω voltage from the temperature sensor on each of a plurality of frequency bands that are different from one another;
in response to a shorter-term moving average of the resistance thermography 30 voltage on one or more of the plurality of frequency bands deviating from a longer-term moving average of the resistance thermography 3ω voltage by more than a predetermined threshold, starting an alarm process; and
control the alarm process.
